(19) United States
(12) Patent Application Publication
(10) Pub. No.: US 2007/0001285 A1
(43) Pub. Date: Jan. 4, 2007

(54) Apparatus having reduced warpage in an over-molded IC package

(76) Inventors: Hem Takiar, Fremont, CA (US); Shrikar Bhagath, San Jose, CA (US); Ken Jian Ming Wang, San Francisco, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/170,883

(22) Filed: Jun. 30, 2005

(51) Int. Cl. H01L 23/12

(52) U.S. Cl. 257/700; 257/E23.01

(57) ABSTRACT

A dummy circuit pattern is disclosed on a surface of a substrate for a semiconductor package, the dummy circuit pattern including straight line segments having a length controlled so as not to generate stresses within the line segments above a desired stress. The dummy circuit pattern may be formed of lines, or contiguous or spaced polygons, such as hexagons. Portions of the dummy circuit pattern may also be formed with an orientation, size and position that are randomly selected.

### CROSS REFERENCE TO RELATED APPLICATION

The present application is related to U.S. Patent Application Ser. No. ______, to Hem Takiar et al., entitled, “METHOD FOR REDUCING WARPAGE IN AN OVER-MOLDED IC PACKAGE,” which application is filed concurrently herewith and which application is incorporated by reference in its entirety herein.

The present application is related to U.S. Patent Application Ser. No. ______, to Cheeman Yu et al., entitled, “SUBSTRATE WARPAGE CONTROL AND CONTINUOUS ELECTRICAL ENHANCEMENT,” which application is filed concurrently herewith and which application is incorporated by reference in its entirety herein.

### BACKGROUND OF THE INVENTION

1. Field of the Invention

Embodiments of the present invention relate to a method of forming a chip carrier substrate to prevent warping, and a chip carrier formed thereby.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

One exemplary standard for flash memory cards is the so-called SD (Secure Digital) flash memory card. In the past, electronic devices such as SD cards have included an integrated circuit (“IC”) system consisting of several individually packaged ICs each handling different functions, including logic circuits for information processing, memory for storing information, and I/O circuits for information exchange with the outside world. The individually packaged ICs have been mounted separately on a substrate such as a printed circuit board to form the IC system. More recently, system-in-a-package (“SiP”) and multichip modules (“MCM”) have been developed where a plurality of integrated circuit components have been packaged together to provide a complete electronic system in a single package. Typically, an MCM includes a plurality of chips mounted side by side on a substrate and then packaged. An SiP typically includes a plurality of chips, some or all of which may be stacked on a substrate and then packaged.

The substrate on which the die and passive components may be mounted in general includes a rigid or soft dielectric base having a conductive layer etched on one or both sides. Electrical connections are formed between the die and the conductive layer(s), and the conductive layer(s) provide an electric lead structure for integration of the die into an electronic system. Once electrical connections between the die and substrate are made, the assembly is then typically encased in a molding compound to provide a protective package.

One surface of a conventional substrate 20 including an etched conductive layer is shown in FIG. 1. The substrate 20 includes a conductance pattern 22 for transferring electrical signals between the various components mounted on the substrate, as well as between the substrate components and the external environment. The conductance pattern may have any number of configurations and occupy various amounts of space on the substrate. In that past it has been recognized that if the conducting layer on a surface of the substrate is completely etched away from the areas not forming part of the conductance pattern, this results in areas of different thermal expansion properties, and a build up of mechanical stresses in the substrate upon heating of the substrate during IC package fabrication. The metal of the conductance pattern tends to expand upon heating, and having some areas with metal and some areas without results is stress generation in the substrate. The same phenomenon was observed where the areas of the conducting layer not forming part of the conducting layer was left completely intact. These stresses tend to warp the substrate. A warped substrate can result in mechanical stresses and cracking of the semiconductor die, either when the semiconductor die is bonded to the substrate, or thereafter.

It is therefore known to etch a so-called dummy pattern on the substrate in areas not used for the conductance pattern. For example, U.S. Pat. No. 6,380,633 to Tsai entitled, “Pattern Layout Structure in Substrate” discloses forming a cross-hatched dummy pattern, such as dummy pattern 24 shown in FIG. 1 formed in regions 26, 28, and 30 on substrate 20 not used for conductance pattern 22. Dummy pattern 24 provides improved semiconductor yields by reducing disparate thermal properties between areas on the substrate having a conductance pattern and areas on the substrate which do not.

The inventors of the present invention have further realized that thermal stresses still result when the dummy pattern 24 is laid down in long straight lines. In particular, it has been found that thermal stresses accumulate over a straight segment of a dummy pattern trace, which thermal stresses increase the longer the length of the straight segment. U.S. Pat. No. 6,864,434 to Chang et al. entitled “Warpage-Preventive Circuit Board And Method For Fabricating The Same” discloses a cross-hatched dummy pattern as proposed in Tsai, but Chang et al. break up the dummy pattern into a plurality of regions. While Chang et al. represent an improvement over Tsai, Chang et al. still disclose a system of straight line segments on the substrate which result in stress in the substrate. As semiconductor die become thinner and more delicate, it becomes even more important to minimize the stresses within the substrate.

### SUMMARY OF THE INVENTION

Embodiments of the present invention, roughly described, relate to a method of forming a chip carrier substrate to prevent warping, and a chip carrier formed thereby. The substrate includes a conductance pattern for transferring electrical signals between die and components on the substrate, and a dummy circuit pattern to prevent warpage of the substrate in areas not occupied by the conductance pattern.

The dummy circuit pattern may have straight line segments with a length controlled so as not to generate stresses within the line segments above a desired stress. The desired length of a line segment may be determined experimentally by determining the stress within a straight segment as a function of length, and then setting the length below a desired maximum stress within a given straight segment. Alternatively, the desired length of a line segment may be estimated based on the known properties of the materials used in the substrate.

The dummy circuit pattern may be formed in a plurality of lines, shapes and sizes. In one embodiment, the dummy circuit pattern may be formed of a plurality of polygons, such as for example hexagons. The polygons may be contiguous with each other, or the polygons may be spaced from each other. Moreover, the polygons may each be the same size as each other, or the dummy circuit pattern may include polygons of different sizes.

In alternative embodiments, the dummy circuit pattern may be formed of randomly shaped polygons formed on the substrate. The random shapes may also be randomly oriented and/or randomly positioned on the substrate. The random shapes may be contiguous with each other, or they may be spaced from each other in alternative embodiments.

As an alternative to random shapes, the dummy circuit pattern may further be formed of random lines on the substrate. The lines may have a random orientation, random length and/or a random position on the dummy circuit pattern in alternative embodiments.

The dummy circuit pattern may be formed on a photomask, along with the conductance pattern, and then etched into the conductive layers on the top and/or bottom of the substrate in a known etching process.

### BRIEF DESCRIPTION OF THE DRAWINGS

FIG. 1 is a top view of a prior art substrate including a cross-hatched dummy circuit pattern.

FIG. 2 is a top view of a substrate including a conductance pattern and a dummy circuit pattern according to embodiments of the present invention in regions not occupied by the conductance pattern.

FIG. 3 is a cross-sectional view of the substrate shown in FIG. 2.

FIG. 4 is a top view of a substrate including a conductance pattern and a dummy circuit pattern according to an alternative embodiment of the present invention.

FIG. 5 is a top view of a substrate including a conductance pattern and a dummy circuit pattern according to a second alternative embodiment of the present invention.

FIG. 6 is a top view of a substrate including a conductance pattern and a dummy circuit pattern according to a third alternative embodiment of the present invention.

FIG. 7 is a top view of a substrate including a conductance pattern and a dummy circuit pattern according to a fourth alternative embodiment of the present invention.

FIG. 8 is a top view of a substrate including a conductance pattern and a dummy circuit pattern according to a fifth alternative embodiment of the present invention.

FIG. 9 is a cross-sectional side view of a substrate including a plurality of conductive layers, one or more of which may include a dummy circuit pattern as shown in any of the above-described embodiments.

FIG. 10 is a cross-sectional side view of a semiconductor package including a substrate having a dummy circuit pattern according to an embodiment of the present invention.

FIG. 11 is a flow chart illustrating a process for fabricating the conductance pattern and dummy circuit pattern on a substrate.

FIG. 12 is an overall flowchart of a process for fabricating a semiconductor package including a dummy circuit pattern according to embodiments of the present invention.

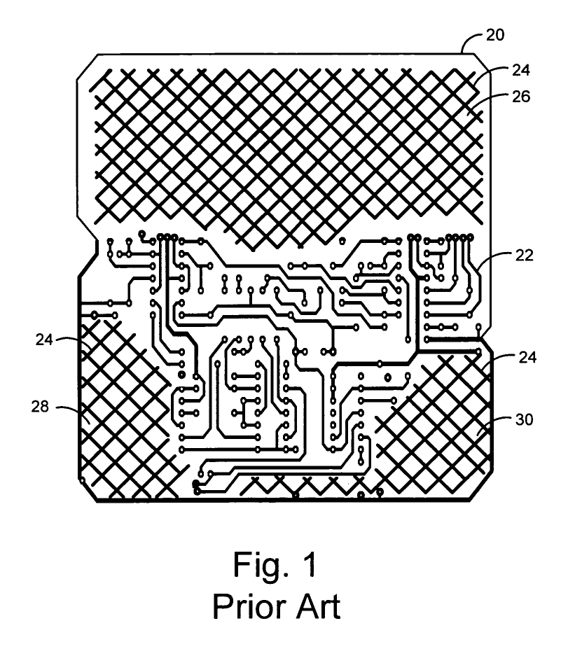

### DETAILED DESCRIPTION

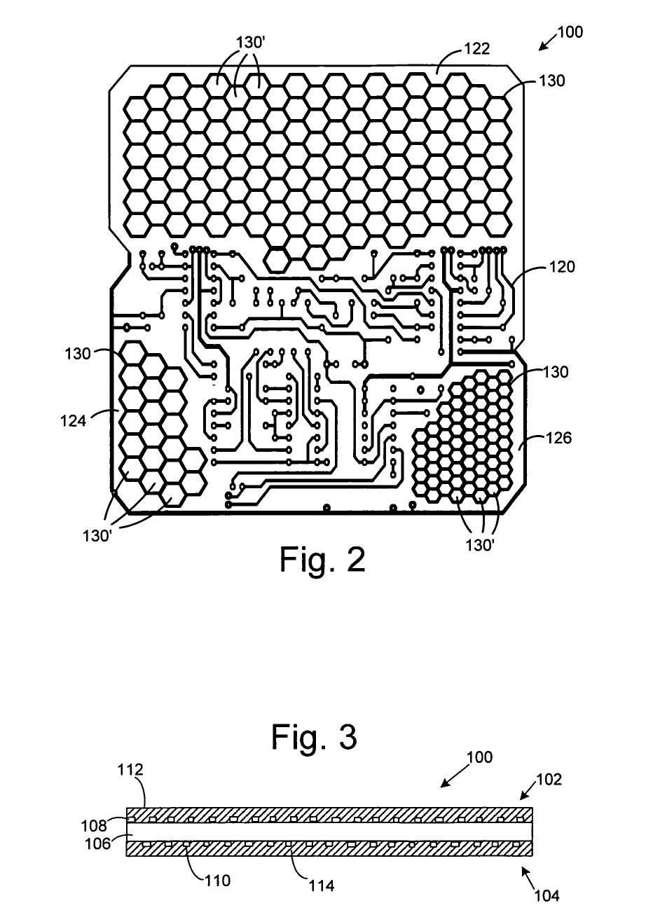

Embodiments of the invention will now be described with reference to FIGS. 2-12, which relate to a method of forming a reduced warpage semiconductor package, and the semiconductor package formed thereby. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

FIG. 2 is a top view of a chip carrier substrate 100, and FIG. 3 is a cross-sectional view through a plane normal to the top and bottom surfaces of substrate 100. As seen in FIG. 3, substrate 100 may have a top surface 102 and a bottom surface 104. Substrate 100 may be formed of an electrically insulative core 106 having a top conductive layer 108 formed on a top surface of the core and a bottom conductive layer 110 formed on a bottom surface of the core. The core may be formed of various dielectric materials such as for example, polyimide laminates, epoxy resins including FR4 and FR5, bismaleimide triazine (BT), and the like. Although not critical to the present invention, core 106 may have a thickness of between 40 microns (μm) to 200 μm, although thickness of the core may vary outside of that range in alternative embodiments. The core may be ceramic or organic in alternative embodiments.

The conductive layers 108 and 110 may be formed of copper, copper alloy or other low resistance electrical conductor, and may be patterned in a conductance pattern and dummy circuit according to embodiments of the present invention as explained hereinafter. The layers 108 and/or 110 may have a thickness of about 10 μm to 24 μm, although the thickness of the layers 108 and 110 may vary outside of that range in alternative embodiments. Once patterned, the top and bottom conductive layers may be laminated with a solder mask 112, 114, respectively, as is known in the art.

Substrate 100 may be patterned and configured for use in a wide variety of semiconductor packages. One such package is a so-called land grid array (LGA) semiconductor package used, for example, in SD Flash Memory Cards. However, it is understood that the dummy circuit pattern explained hereinafter may be used on any substrate in which a conductance pattern may be formed and assembled into a semiconductor device.

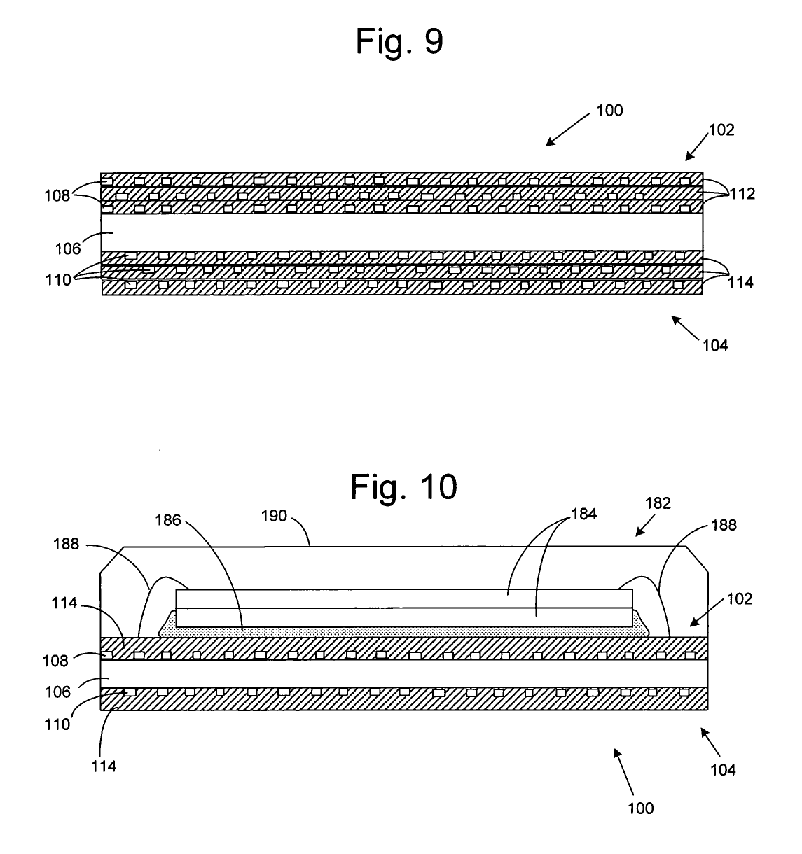

Referring again to FIG. 2, one or both of the conductive layers 108 and 110 may be etched or otherwise processed as explained hereinafter so as to include a conductance pattern 120 to provide electrical connection between components mounted to substrate 100, as well as between components on substrate 100 and external devices. In embodiments including conductance patterns on both the top surface 102 and bottom surface 104 of substrate 100, as well as in substrates including a plurality of top and bottom layers (as explained hereinafter with respect to FIG. 9), vias (not shown) may be provided to transmit electrical signals between the conductance patterns in different layers.

Substrate 100 further includes a plurality of regions 122, 124, 126 not having a conductance pattern, referred to herein as dummy circuit regions. A dummy circuit pattern 130 according to embodiments of the present invention may be formed in one or more of the dummy circuit regions 122, 124, and 126. It is understood that the size and shape of substrate 100, as well as the size and shape of conductance pattern 102 may vary greatly in alternative embodiments of the present invention so as to define one or more dummy circuit regions of any size or shape. Dummy circuit 130 may be provided in any one or more of these dummy circuit regions. In embodiments, a dummy circuit pattern according to any of the embodiments described hereinafter may be provided on both sides of the substrate, even where a conductance pattern is provided only on one side of the substrate. It is conceivable that a substrate may be used in a semiconductor device which does not include a conductance pattern on either first or second opposed surfaces of the substrate. Such a substrate may be formed with a dummy circuit pattern according to embodiments of the present invention.

In each of the embodiments described hereinafter, the dummy circuit pattern is comprised of lines and/or shapes. The lines and/or shapes are provided in a given density in the one or more dummy circuit regions. Density refers to the number, length and/or amount of material in the conductive traces forming a dummy circuit pattern, or the conductance pattern, per a unit of area on the substrate.

The stress level within a straight segment in a portion of a dummy circuit pattern will be linearly or non-linearly related to the length of that straight segment when the substrate is heated. In general, the longer the length, the greater the stress upon heating.

With regard to the maximum length of a straight segment in any portion of a dummy circuit pattern according to the embodiments described hereinafter, the length of a straight segment may be set to maintain the stresses within that straight segment below a desired level. In particular, the stress per unit length of a straight segment of a portion of the dummy circuit may be determined experimentally and/or by known physical characteristics and behavior of the substrate materials as a function of the type of the materials used, the thicknesses of the materials used and the temperature range to which the materials are to be subjected. Other characteristics may be included in the analysis.

Given this information, the maximum length of a straight segment of a portion of the dummy circuit may be selected to maintain the stresses within that segment below any desired, predetermined level. Stated another way, with a knowledge of the stress build-up per unit length, a desired maximum stress may be selected, and then the length of all or a portion of the straight segments in a dummy circuit may be set to maintain a stress at or below the selected stress level. It is understood that a quantitative analysis of stress per unit length need not be performed, and the maximum length of a straight segment may instead be estimated in embodiments of the invention. It is also understood that a dummy circuit pattern may include straight segments in which stresses exceeding a predetermined maximum may result in those segments upon heating in embodiments of the invention.

Regarding the density of a dummy circuit pattern, without regard to other factors which may contribute to stress within a substrate, stresses within the substrate may be minimized when the density of the dummy pattern approximates that of the conductance pattern. Thus, the density of a dummy circuit pattern may be selected to approximate that of a given conductance pattern on a substrate in embodiments of the invention. Alternatively, the density of the dummy circuit pattern may be selected to be greater or lesser than the density of the conductance pattern, such that the resulting stresses on the substrate remain within predetermined acceptable levels. It is understood that a quantitative analysis of stress resulting from a difference in densities between the dummy circuit pattern and conductance pattern need not be performed, and the density of the dummy circuit pattern may instead be estimated in embodiments of the invention.

In the embodiment shown in FIG. 2, the dummy circuit pattern 130 is formed of a plurality of contiguous, aligned cells 130′ etched into layer 108 and/or 110. Each of the contiguous cells may be uniform in shape, and fit together so as not to leave any spaces between the cells. It is understood that individual cells may fit together so as to leave a space therebetween in alternative embodiments. Pattern 130 is etched or otherwise processed so that no straight line extends through any two contiguous cells 130′. In the embodiment shown in FIG. 2, the individual cells 130′ are hexagonal, forming a honeycomb pattern 130. However, it is understood that other shapes may be used in alternative embodiments, such as for example, contiguous circles, octagons, and other polygons besides triangles, rectangles, and squares. (Triangles, rectangles, and squares may be used where adjacent shapes are not aligned with each other so that no straight line extends through any two contiguous shapes).

As indicated, the length of the various straight segment traces forming the pattern 130 may be controlled to maintain the stress generation within the straight segments below a predetermined, desired stress level. However, in embodiments, the length of the straight segments forming each cell 130′ may range between about 50 μm and 250 μm, and more particularly between 70 μm and 150 μm. It is understood to the maximum length of a cell 130′ segment may have a maximum diameter larger than 250 μm and smaller than 50 μm in alternative embodiments. In embodiments, the width of the individual traces forming the various sides of each cell 130′ may be between approximately 70 μm and 150 μm, although the width of each cell may be larger or smaller than that in alternative embodiments of the present invention. Each of the dummy circuit regions 122 through 126 may include the same sized cells 130′. Alternatively, as shown in FIG. 2, the cells in one or more regions (122, 124) may be larger than the cells 130′ in other dummy circuit regions (126). As indicated above, dummy circuit pattern 130 may be omitted from one or more of the dummy circuit regions. Moreover, as explained hereinafter, individual cells 130′ within a given dummy circuit region may be of different sizes.

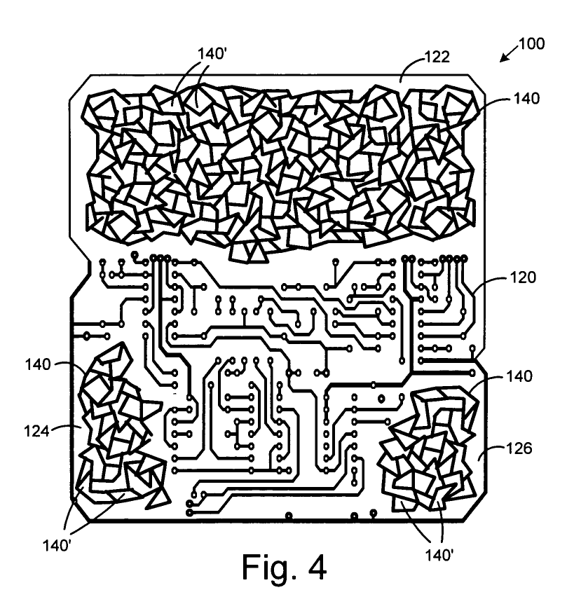

In the embodiment of FIG. 2, each individual cell 130′ had a uniform shape. In a second alternative embodiment shown in FIG. 4, one or more of the dummy regions 122, 124, and 126 may include a dummy circuit pattern 140 including a plurality of irregular, randomly shaped cells 140′. The random shapes of cells 140′ may be created in the pattern mask laid down on the substrate as explained hereinafter. A controller for creating the pattern mask may include software for generating random shapes. Alternatively, the configuration of the random shapes may be created, and then the information transferred to the system that creates the pattern mask. While FIG. 4 shows randomly shaped, straight-edged polygons, one or more of the cells 140′ may have rounded edges in alternative embodiments of the present invention.

In embodiments, each randomly shaped cell 140′ may each be positioned at a random location within a given dummy circuit region. Alternatively, each dummy circuit region may be subdivided into predefined sub-regions, and the cell distribution across the various sub-regions controlled, but the positioning of a cell 140′ within a given sub-region randomly determined. As a further alternative, the position of each randomly shaped cell may be predetermined within a dummy circuit region.

As in the embodiment of FIG. 2, in general, no two adjacent cells 140′ will have a continuous straight line extending therethrough. While it is possible that edges of two randomly shaped cells will align in this embodiment, the likelihood of any two randomly shaped adjacent cells having aligning sides forming a straight line therebetween in exceedingly small. The average length of any side in a randomly shaped cell 140′ may range between 0.3 mm and 1 mm in an embodiment of the present invention. However, it is appreciated that the average size of any side of a randomly shaped cell 140′ may be greater or smaller than that range in alternative embodiments of the present invention. Additionally, it is understood that the standard deviation from that average size may vary in alternative embodiments of the present invention. In embodiments, the thickness of the lines 140′ may be approximately 50 μm, but this may vary in embodiments of the invention.

The average size of the randomly shaped cells 140′ may be the same or different in the different dummy circuit regions 122-126. Similarly, the dummy circuit pattern 140 may be omitted from one or more of the dummy circuit regions 122-126. The density of the dummy circuit pattern 140 may be controlled to be generally the same as, less than or greater than the density of the conductance pattern 120 as described above.

In the embodiment shown in FIG. 4, all or a majority of the cells 140′ are closed polygons. In a third embodiment shown in FIG. 5, a chip-carrying substrate 100 may include a conductance pattern 120 and one or more dummy circuit regions 122-126, each including a dummy circuit pattern 150 comprised of randomly oriented lines 150′. Lines 150′ may be straight or curved. Where straight, the length of each line 150′ may be selected to be less than a predetermined length. Alternatively, the average length of all lines 150′ may be selected to be below a predetermined. Similarly, the density of the lines within a dummy circuit pattern 150 may approximate the density of the conductance pattern, or may be greater than or lesser than the density of the conductance pattern as described above. In embodiments, the thickness of the lines 150′ may be approximately 50 μm, but this may vary in embodiments of the invention.

In the embodiment shown, the lines 150′ are randomly oriented, randomly sized (within a given range), and randomly positioned. It is understood that one or more of the orientation, length, and location of the lines 150′ may be controlled so as not to be random in alternative embodiments. Thus, for example, the orientation and position may be random but the length of the lines within pattern 150 may be controlled. Alternatively, the orientation and position of the lines in pattern 150 may be random, but the position partially or completely controlled. Similarly, the length and position of lines 150′ may be random and their orientation controlled. Each of the above described properties of lines 150′ may be the same for each dummy circuit region, or the above-described properties may vary from one dummy circuit region to the next.

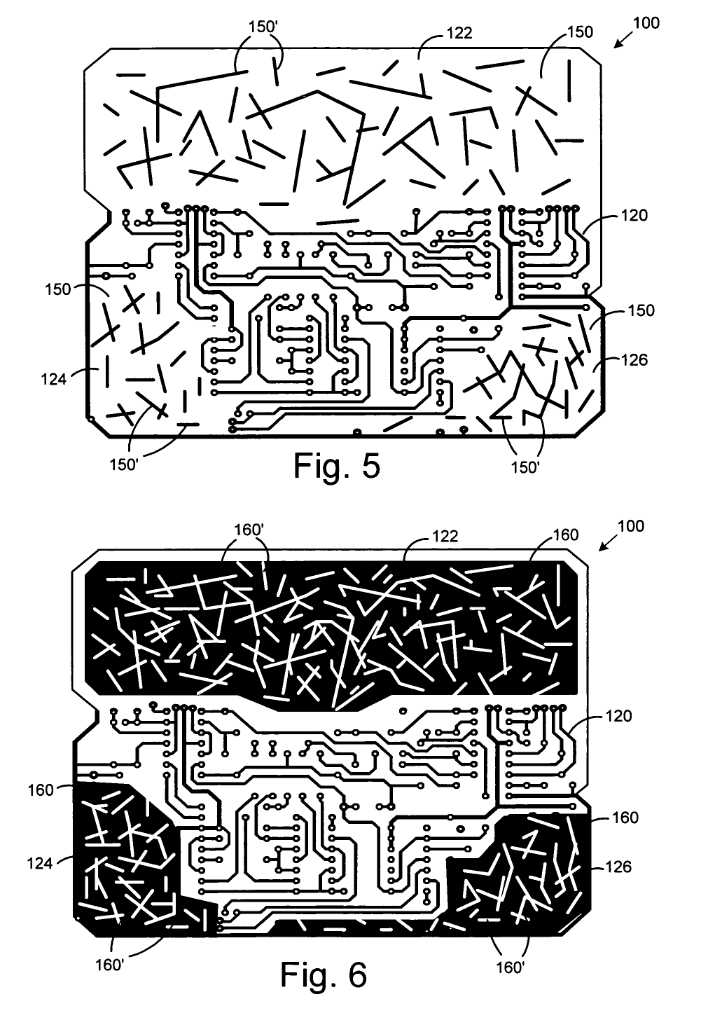

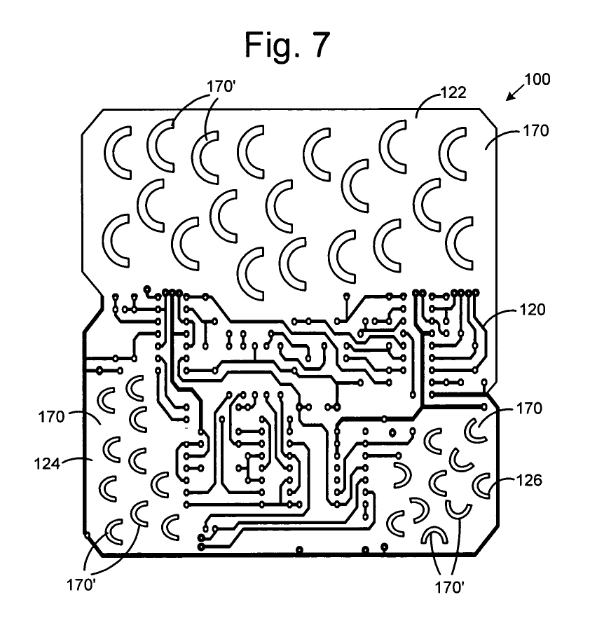

FIG. 6 shows a further embodiment of the present invention, including a substrate 100 having a conductance pattern 120 and dummy circuit regions 122 through 126. In the embodiments described thus far, the lines and shapes shown in the drawings as the dummy circuit patterns represent trace material that is left behind on the substrate after the pattern is etched or otherwise formed on the substrate. By contrast, in the embodiment of FIG. 6, the dummy circuit regions each include a dummy circuit pattern 160 wherein the white lines in the drawing represent material that is etched away during the fabrication process, and the dark background represents material from layers 108 or 110 that is left behind after the dummy circuit pattern is formed. The dummy circuit pattern 160 in FIG. 6 may be thought of as a “negative” of the dummy circuit pattern 150 shown in FIG. 5. In alternative embodiments of the present invention, a dummy circuit pattern may comprise the negative of the dummy circuit patterns shown in FIGS. 2-4 and FIGS. 7 and 8 described hereinafter.

Dummy circuit pattern 160 includes etched lines 160′. Etched lines 160′ may have any of the properties of lines 150′ from dummy circuit pattern 150 in FIG. 5. In the embodiment of FIG. 6, the length and density of the lines 160′ are preferably selected to reduce the amount of material in layer 108 or 110 after fabrication to maintain the stress levels within dummy circuit pattern 160 and substrate 100 in general to predetermined acceptable levels as described above.

FIG. 7 shows a further embodiment of the present invention including a substrate 100 having a conductance pattern 120 and dummy circuit regions 122-126. One or more of the dummy circuit regions may include a dummy circuit pattern 170 comprised of a plurality of shapes 170′. In the embodiment shown in FIG. 7, each of the shapes 170′ approximates the outline of the letter “C” with the material from within the outline being etched away during the fabrication process. It is understood that a wide variety of other outline shapes be provided in alternative embodiments of the present invention. The shapes may alternatively be “filled in.” That is, the material from within the outer outline of the shape may remain after the etching process.

In the embodiment shown, the majority of segments forming the shapes 170′ are curved. Curved shapes have an advantage in that stresses within the shape are minimized. Moreover, semiconductor die and other components are more sensitive to patterns on the substrate that are aligned along the axes of the die and component(s). A curved shape reduces stresses that may otherwise result in a semiconductor die or other component mounted above the shape on the substrate. However, it is understood the shapes 170′ may be defined by all or partial straight lines in alternative embodiment of the present invention.

As shown in FIG. 7, each of the shapes 170′ are spaced from each other of the shapes 170′. It is understood that the shapes may overlap in alternative embodiments of the invention. Moreover the shapes may each be in the same orientation (as in dummy circuit regions 122 and 124), or the orientations of the shapes 170′ may differ (as in dummy circuit region 126). The size of each of the shapes 170′ within a given dummy circuit region may be the same or different than each other, and the size of the shapes 170′ from one dummy region to the next may be the same or different (as shown in FIG. 7). The number, size, and/or position of the shapes 170′ may be controlled in each dummy circuit region or may be random.

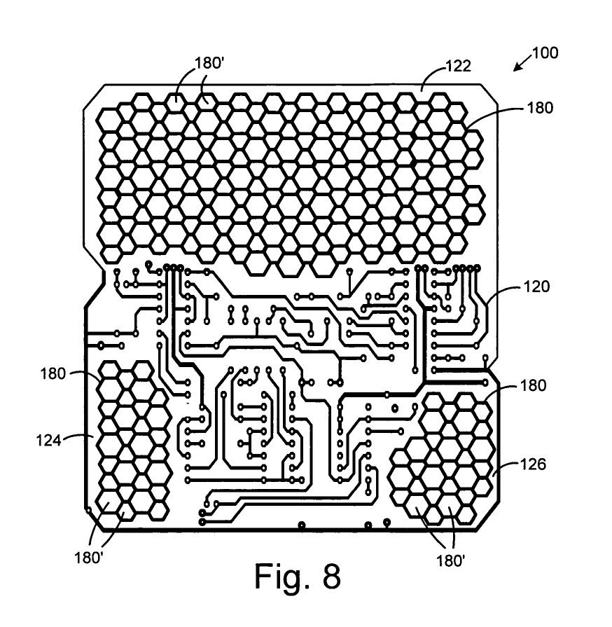

FIG. 8 illustrates a further embodiment of the present invention, including a substrate 100 having a conductance pattern 120 and one or more dummy circuit regions 122-126. One or more of the dummy circuit regions 122-126 may include a conductance pattern 180 formed of a plurality of cells 180′. FIG. 8 is similar to the embodiment of FIG. 2 described above, with the difference that the cells 180′ forming dummy circuit pattern 180 may not each have the same size or shape as each other cell 180′. In the embodiment shown in FIG. 8, a plurality of larger hexagonal cells 180′ are joined by a plurality of smaller hexagonal cells 180′. The cells 180′ may have the properties described above with respect to cells 130′ of FIG. 2.

As indicated above, a plurality of layers 108 and 110 may be provided on the respective upper and lower surfaces of core 106 in substrate 100 in embodiments of the invention. Such an embodiment is shown in cross-section in FIG. 9. In the embodiment shown, core includes three layers 108, each laminated by a layer of solder mask 112 on the top surface 102, and substrate 100 includes three layers 110, each laminated by a layer solder mask 114 on lower surface 104. One or more of the layers 108 and 110 may include a conductance pattern 120 and any of the above-described embodiments of a dummy circuit pattern. The dummy circuit pattern in the various layers 108 may align with each other or not align with each other in embodiments of the invention. The same is true for the dummy circuit patterns formed in layers 110.

FIG. 10 is a cross-sectional view of a semiconductor package 182 which may be formed with a substrate 100 including a dummy circuit pattern according to any of the above-described embodiments. Although not critical to the present invention, FIG. 10 shows two stacked semiconductor die 184 on the top surface 102 of substrate 100. Embodiments of the invention may operate with a single die or between three and eight or more stacked die in an SiP, MCM, or other type of arrangement. Again, while not critical to the present invention, the one or more die 184 may be a flash memory chip (NOR/NAND), SRAM, or DDT, and/or a controller chip such as an ASIC. Other silicon chips are contemplated.

The dummy circuit pattern according to embodiments of the present invention described above controls and/or minimizes mechanical stresses on, and warping of, the substrate 100. This in turn results in control over and/or minimizing of the stresses seen by die 184, thus improving overall yield.

The one or more die 184 may be mounted on the top surface 102 of the substrate 100 in a known adhesive or eutectic die bond process, using a known die attach compound 186. The one or more die 184 may be electrically connected to conductive layers 108, 110 of the substrate 100 by wire bonds 188 in a known wire bond process. After the wire bond process, the circuit may be packaged in a molding compound 190 in a known molding process to complete the package 182.

In addition to reducing stress and warpage, the dummy circuit pattern according to the various embodiments described above may also serve electrical functions. The dummy circuit pattern may provide a path to ground (VSS) or be connected to a power source (VDD) to supply power to the semiconductor die and/or other components mounted on the substrate. Alternatively, the dummy circuit pattern may carry signals to and/or from the semiconductor die and substrate components. In further embodiments, the dummy circuit pattern may be “floating,” i.e., it has no electrical function.

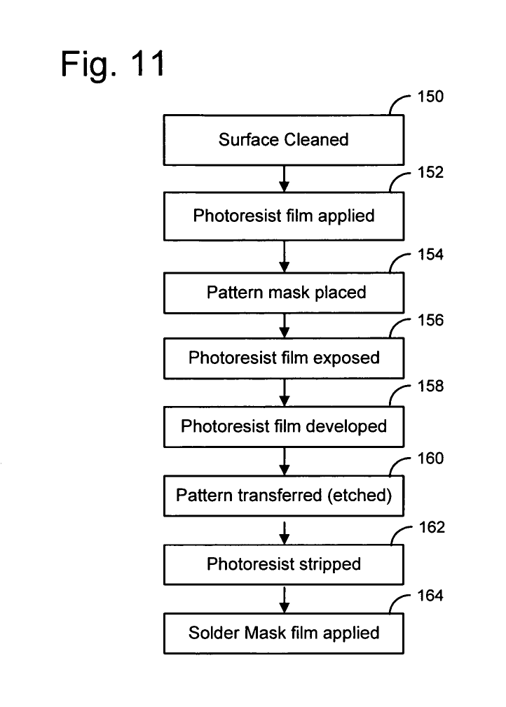

There are a number of known processes for forming the conductance pattern 120 and various embodiments of the dummy circuit pattern on substrate 100. One such process is explained with reference to the flowchart of FIG. 11. The surfaces of conductive layers 108 and 110 are cleaned in step 150. A photoresist film is then applied over the surfaces of layers 108 and 110 in step 152. A pattern photomask containing the outline of the electrical conductance pattern and the dummy circuit pattern is then placed over the photoresist film in step 154. The dummy circuit pattern and the conductance pattern may be formed on the photomask in a known process. As indicated above, where the dummy circuit pattern includes the formation of random lines or shapes on the substrate, a known random generation process may be associated with the photomask formation to include the random lines or shapes, depending on the embodiment of the invention.

Once the photomask is applied over the photoresist film, the photoresist film is exposed (step 156) and developed (step 158) to remove the photoresist from areas on the conductive layers that are to be etched. The exposed areas are next etched away using an etchant such as ferric chloride in step 160 to define the conductance and dummy circuit patterns on the core. Next, the photoresist is removed in step 162, and the solder mask layer is applied in step 164.

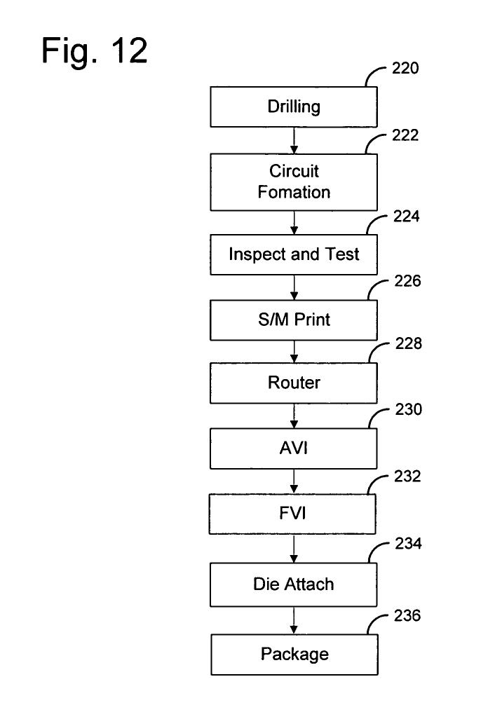

An overall process for forming the finished die package 182 is explained with reference to the flow chart of FIG. 12. The substrate 100 starts out as a large panel which is separated into individual substrates after fabrication. In a step 220, the panel is drilled to provide reference holes off of which the position of the respective substrates is defined. The conductance pattern and dummy circuit pattern are then formed on the respective surfaces of the panel in step 222 as explained above. The patterned panel is then inspected and tested in step 224. Once inspected, the solder mask is applied to the panel in step 226. A router then separates the panel into individual substrates in step 228. The individual substrates are then inspected and tested again in an automated step (step 230) and in a final visual inspection (step 232) to check electrical operation, and for contamination, scratches and discoloration. The substrates that pass inspection are then sent through the die attach process in step 234, and the substrate and dice are then packaged in step 236 in a known injection mold process to form a JEDEC standard (or other) package. It is understood that the die package 182 including a dummy circuit pattern may be formed by other processes in alternative embodiments.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A dummy circuit pattern formed on a surface of a substrate for a semiconductor package, the dummy circuit pattern comprising:
a first shape;
a second shape proximate to the first shape, an outline of the first and second shapes including no straight line segment extending through the first and second shapes.

2. A dummy circuit pattern formed on a surface of a substrate for a semiconductor package as recited in claim 1, wherein portions of the dummy circuit pattern are connected to at least one of ground potential and power potential.

3. A dummy circuit pattern formed on a surface of a substrate for a semiconductor package as recited in claim 1, wherein portions of the dummy circuit pattern are connected to at least one of a semiconductor die and electrical components on the substrate to carry electrical signals to and/or from at least one of the semiconductor die and electrical components on the substrate.

4. A dummy circuit pattern formed on a surface of a substrate for a semiconductor package as recited in claim 1, wherein portions of the dummy circuit pattern are floating.

5. A dummy circuit pattern formed on a surface of a substrate for a semiconductor package as recited in claim 1, wherein the first and second shapes are contiguous.

6. A dummy circuit pattern formed on a surface of a substrate for a semiconductor package as recited in claim 1, wherein the first and second shapes are spaced from each other.

7. A dummy circuit pattern formed on a surface of a substrate for a semiconductor package as recited in claim 1, wherein the first and second shapes are polygons each having sides of the same length.

8. A dummy circuit pattern formed on a surface of a substrate for a semiconductor package as recited in claim 1, wherein the first and second shapes have random shapes.

9. A dummy circuit pattern formed on a surface of a substrate for a semiconductor package as recited in claim 1, wherein the first and second shapes are material from a conductive layer on the substrate, which material is left behind after etching away surrounding portions of the conductive layer.

10. A dummy circuit pattern formed on a surface of a substrate for a semiconductor package as recited in claim 1, wherein the first and second shapes are defined by etching away material so that material left unetched forms an outline defining the first and second shapes.

11. A dummy circuit pattern formed on a surface of a substrate for a semiconductor package as recited in claim 1, wherein the first and second shapes are one of a hexagon, an octagon and a circle.

12. A dummy circuit pattern formed on a surface of a substrate for a semiconductor package, the dummy circuit pattern comprising:
a straight line segment having a length based on a length determined to maintain stress within the straight line segment below a given stress level.

13. A dummy circuit pattern formed on a surface of a substrate for a semiconductor package as recited in claim 12, wherein the given stress level is estimated.

14. A dummy circuit pattern formed on a surface of a substrate for a semiconductor package as recited in claim 12, wherein the straight line forms part of a polygon having sides of equal length.

15. A dummy circuit pattern formed on a surface of a substrate for a semiconductor package as recited in claim 12, wherein the straight line segment has at least one of a random orientation in the dummy circuit pattern, a random length in the dummy circuit pattern and a random position within the dummy circuit pattern.

16. A dummy circuit pattern formed on a surface of a substrate for a semiconductor package as recited in claim 12, further comprising a plurality of additional line segments, the straight line segment and the plurality of additional line segments having a density approximating the density of a conductance pattern also formed on the surface of the substrate.

17. A dummy circuit pattern formed on a surface of a substrate for a semiconductor package, the dummy circuit pattern comprising:
a plurality of hexagonal cells, first and second cells of the plurality of hexagonal cells being contiguous with each other.

18. A dummy circuit pattern formed on a surface of a substrate for a semiconductor package as recited in claim 17, wherein the plurality of hexagonal cells are contiguous.

19. A dummy circuit pattern formed on a surface of a substrate for a semiconductor package as recited in claim 17, wherein the plurality of hexagonal cells are spaced from each other.

20. A dummy circuit pattern formed on a surface of a substrate for a semiconductor package as recited in claim 17, wherein the plurality of hexagonal cells are the same size.

21. A dummy circuit pattern formed on a surface of a substrate for a semiconductor package as recited in claim 17, wherein a first portion of the plurality of hexagonal cells is a different size than a second portion of the plurality of hexagonal cells.

22. A dummy circuit pattern formed on a surface of a substrate for a semiconductor package as recited in claim 17, wherein the first and second shapes are material from a conductive layer on the substrate, which material is left behind after etching away surrounding portions of the conductive layer.

23. A dummy circuit pattern formed on a surface of a substrate for a semiconductor package, the dummy circuit pattern comprising:
a plurality of lines, at least one of a length, orientation and position of the plurality of lines within the dummy circuit pattern being randomly selected.

24. A dummy circuit pattern formed on a surface of a substrate for a semiconductor package as recited in claim 23, wherein the plurality of lines form random shapes.

25. A dummy circuit pattern formed on a surface of a substrate for a semiconductor package as recited in claim 23, wherein the plurality of lines form randomly shaped polygons.

26. A dummy circuit pattern formed on a surface of a substrate for a semiconductor package as recited in claim 23, wherein the plurality of lines are material from a conductive layer on the substrate, which material is left behind after etching away surrounding portions of the conductive layer.

27. A dummy circuit pattern formed on a surface of a substrate for a semiconductor package as recited in claim 23, wherein the plurality of lines are defined by etching away material so that material left unetched forms an outline defining the first and second shapes.

28. A dummy circuit pattern formed on a surface of a substrate for a semiconductor package as recited in claim 23, wherein the first and second shapes are one of a hexagon, octagon and circle having at least one of a random orientation and random position within the dummy circuit pattern.

29. A semiconductor package, comprising:
a substrate;
a conductance pattern formed on a surface of the substrate;
a dummy circuit pattern formed on the surface of a substrate, the dummy circuit pattern including a straight line segment having a length based on a length determined to maintain stress within the straight line segment below a given stress level.

30. A semiconductor package as recited in claim 29, wherein portions of the dummy circuit pattern are connected to at least one of ground potential and power potential.

31. A semiconductor package as recited in claim 29, wherein portions of the dummy circuit pattern are connected to at least one of a semiconductor die and electrical components on the substrate to carry electrical signals to and/or from at least one of the semiconductor die and electrical components on the substrate.

32. A semiconductor package as recited in claim 29, wherein portions of the dummy circuit pattern are floating.

33. A semiconductor package as recited in claim 29, wherein the straight line forms part of a polygon having sides of equal length.

34. A semiconductor package as recited in claim 29, wherein the straight line segment has at least one of a random orientation in the dummy circuit pattern, a random length in the dummy circuit pattern and a random position within the dummy circuit pattern.
